(19) United States
(12) Patent Application Publication
(10) Pub. No.: US 2024/0268143 A1
(43) Pub. Date: Aug. 8, 2024

(54) LIGHT-EMITTING DEVICE, AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Shengde Zhang, Beijing (CN); Ruiqian Xu, Beijing (CN); De Yuan, Beijing (CN); Can Zhang, Beijing (CN); Jie Xiang, Beijing (CN); Jian Yang, Beijing (CN); Fei Shang, Beijing (CN); Liang Cao, Beijing (CN); Xu Gong, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/020,467

(22) PCT Filed: May 26, 2022
(86) PCT No.: PCT/CN2022/095200

§ 371 Date: Feb. 9, 2023

(51) Int. Cl. H10K 50/17; H10K 50/13; H10K 101/40

(52) U.S. Cl. CPC H10K 50/171; H10K 50/13; H10K 2101/40

(57) ABSTRACT

The present disclosure provides a light-emitting device, and a display apparatus. The light-emitting device includes a luminescent layer including a first sublayer, a second sublayer and a third sublayer, and the second sublayer is disposed between the first sublayer and the third sublayer; the second sublayer includes host materials and guest materials; under the action of external energy, excitons are compounded in the second sublayer; the first sublayer and the third sublayer both include the host materials; a concentration of the excitons in the second sublayer is greater than a concentration of the excitons in the first sublayer, and the concentration of the excitons in the second sublayer is greater than a concentration of the excitons in the third sublayer.

### TECHNICAL FIELD

The present application relates to the technical field of displaying, and particularly relates to a light-emitting device, and a display apparatus.

### BACKGROUND

With the development of science and technology, organic light emitting diode (OLED) display devices have been widely used. At present, users have higher and higher requirements for the performance of OLED display devices, for example, they hope that the product life will be longer.

However, due to the differences in existing materials, device structures, etc., OLED display devices cannot achieve a longer service life in actual use, resulting in poor user experience.

### SUMMARY

The embodiments of the present application employ the following technical solutions:

In one aspect, an embodiment of the present application provides a light-emitting device, including:
a luminescent layer including a first sublayer, a second sublayer and a third sublayer, wherein the second sublayer is disposed between the first sublayer and the third sublayer; the second sublayer includes host materials and guest materials; under the action of external energy, excitons are compounded in the second sublayer;
wherein the first sublayer and the third sublayer both include the host materials; a concentration of the excitons in the second sublayer is greater than a concentration of the excitons in the first sublayer, and the concentration of the excitons in the second sublayer is greater than a concentration of the excitons in the third sublayer.

Optionally, the first sublayer and the third sublayer are single-layer structures, and both include the host materials.

Optionally, the light-emitting device further includes a hole injection layer disposed on a side of the first sublayer away from the second sublayer; and
a range of an absolute value of a difference between an energy value of a highest occupied molecular orbital HOMO of the first sublayer and an energy value of a highest occupied molecular orbital HOMO of the second sublayer includes 0.1-0.5 eV.

Optionally, the light-emitting device further includes an electron injection layer disposed on a side of the third sublayer away from the second sublayer; and
a range of an absolute value of a difference between an energy value of a lowest unoccupied molecular orbital LUMO of the third sublayer and an energy value of a lowest unoccupied molecular orbital LUMO of the second sublayer includes 0.1-0.5 eV.

Optionally, along a direction perpendicular to the luminescent layer, a thickness of the second sublayer is greater than a thickness of the first sublayer, and the thickness of the second sublayer is greater than a thickness of the third sublayer.

Optionally, along the direction perpendicular to the luminescent layer, the thickness of the first sublayer is the same as the thickness of the third sublayer.

Optionally, the first sublayer includes a first auxiliary sublayer and a first electron barrier sublayer, the first electron barrier sublayer is disposed between the first auxiliary sublayer and the second sublayer; and
the third sublayer includes a second auxiliary sublayer and a first hole barrier sublayer, the first hole barrier sublayer is disposed between the second auxiliary sublayer and the second sublayer.

Optionally, the first auxiliary sublayer and the second auxiliary sublayer both include the host materials and the guest materials; and
the first hole barrier sublayer includes a hole blocking material, and the first electron barrier sublayer includes an electron blocking material.

Optionally, the first auxiliary sublayer and the second auxiliary sublayer both include the host materials and the guest materials; and
the first hole barrier sublayer includes the host materials, the guest materials and a hole blocking material; the first electron barrier sublayer includes the host materials, the guest materials and an electron blocking material.

Optionally, along a direction perpendicular to the luminescent layer, a thickness of the second sublayer is greater than a thickness of the first hole barrier sublayer, and the thickness of the second sublayer is greater than a thickness of the first electron barrier sublayer.

Optionally, along the direction perpendicular to the luminescent layer, the thickness of the first hole barrier sublayer is the same as the thickness of the first electron barrier sublayer.

Optionally, the first sublayer further includes a second electron barrier sublayer, the second electron barrier sublayer is disposed on a side of the first electron barrier sublayer away from the second sublayer to divide the first auxiliary sublayer into two parts.

Optionally, the second electron barrier sublayer includes the host materials, the guest materials and the electron blocking material; and
a doping concentration of the electron blocking material in the host materials of the second electron barrier sublayer is greater than a doping concentration of the electron blocking material in the host materials of the first electron barrier sublayer.

Optionally, the third sublayer further includes a second hole barrier sublayer, the second hole barrier sublayer is disposed on a side of the first hole barrier sublayer away from the second sublayer to divide the second auxiliary sublayer into two parts.

Optionally, the second hole barrier sublayer includes the host materials, the guest materials and the hole blocking material; and
a doping concentration of the hole blocking material in the host materials of the second hole barrier sublayer is greater than a doping concentration of the hole blocking material in the host materials of the first hole barrier sublayer.

Optionally, the light-emitting device further includes an electron barrier layer and a hole barrier layer, the electron barrier layer is disposed on a side of the first sublayer away from the second sublayer, and the hole barrier layer is disposed on a side of the third sublayer away from the second sublayer:
a distance between the first electron barrier sublayer and an interface of the first auxiliary sublayer and the electron barrier layer is the same as a distance between the first hole barrier sublayer and an interface of the second auxiliary sublayer and the hole barrier layer.

In another aspect, an embodiment of the present application provides a display apparatus including the light-emitting device described above.

The above description is merely a summary of the technical solutions of the present application. In order to more clearly know the technological means of the present application to enable the implementation according to the contents of the description, and in order to make the above and other purposes, features and advantages of the present application more apparent and understandable, the particular embodiments of the present application are provided below.

### BRIEF DESCRIPTION OF THE DRAWINGS

In order to more clearly illustrate the technical solutions of the embodiments of the present application or the related art, the drawings that are required to describe the embodiments or the related art will be briefly described below. Apparently, the drawings that are described below are merely embodiments of the present application, and a person skilled in the art may obtain other drawings according to these drawings without paying creative work.

FIG. 1 is a schematic structural diagram of a light-emitting device in related art;

FIG. 2 is a schematic structural diagram of another light-emitting device in related art;

FIG. 3 is a schematic structural diagram of a light-emitting device according to an embodiment of the present application;

FIG. 4 is a schematic structural diagram of another light-emitting device according to an embodiment of the present application;

FIG. 5 is a schematic structural diagram of yet another light-emitting device according to an embodiment of the present application;

FIG. 6 is a LT95 duration comparison diagram between a comparison instance and the light-emitting device in an embodiment of the present application;

FIG. 7 is an overshoot phenomenon comparison diagram between a comparison instance and the light-emitting device in an embodiment of the present application;

FIG. 8 is an accelerated factor comparison diagram between a comparison instance and the light-emitting device in an embodiment of the present application;

FIG. 9 is a schematic diagram of the evaporation in related art; and

FIG. 10 is a schematic diagram of the evaporation according to an embodiment of the present application.

### DETAILED DESCRIPTION

In order to make the purpose, technical solutions and advantages of the embodiments of the present application clearer, the technical solutions in the embodiments of the present application will be described clearly and completely in combination with the drawings in the embodiments of the present application. Obviously, the described embodiments are part of the embodiments of the present application, not all of them. Based on the embodiments in the present application, all other embodiments obtained by those skilled in the art without creative work fall within the scope of protection in the present application.

In the drawings, thicknesses of the areas and layers may be exaggerated for clarity. The same reference numerals in the drawings represent the same or similar structures, so their detailed description will be omitted. In addition, the drawings are only schematic illustrations of the present application, and are not necessarily drawn to scale.

In the embodiment of the present application, unless otherwise stated, “a plurality of” means two or more: the orientation or position relationship indicated by the term “upper” is based on the orientation or position relationship shown in the drawings, which is only for the convenience of describing the present application and simplifying the description, but not for indicating or implying that the structure or element referred to must have a specific orientation, structure or operation in a specific orientation, so it cannot be understood as a restriction on the application.

Unless otherwise requires in the context, the term “including” or “comprising” is interpreted as “including but not limited to” in the entire specification and claims. In the description of the specification, the terms “an embodiment”, “some embodiments”, “exemplary embodiments”, “examples”, “specific examples” or “some examples” are intended to indicate that specific features, structures, materials or characteristics related to the embodiment or example are included in at least one embodiment or example of the present application. The schematic representation of the above terms does not necessarily refer to the same embodiment or example. In addition, the specific features, structures, materials or features described may be included in any one or more embodiments or examples in any appropriate manner.

In the embodiment of the present application, the words “first”, “second” and other words are used to distinguish the same or similar items with basically the same function and action, only for the purpose of clearly describing the technical solutions of the embodiments of the present application, and cannot be understood as indicating or implying the relative importance or implying the quantity of the indicated technical features.

With the development of science and technology, OLED display apparatus has become more and more widely used due to its advantages of self-illumination, low driving voltage, high luminous efficiency, short response time, high definition and contrast, wide viewing angle, wide temperature range, flexible display and large-area full-color display. At present, mobile phones and other electronic products equipped with OLED display screens are gradually moving from high-end flagship to mid-range products to meet the use needs of more ordinary consumers. In order to pursue the maximization of benefits and product differentiation, mobile phone manufacturers have increasingly high performance requirements for OLED display screens. For example, OLED display screens are required to have good color performance, and have the advantages of long life, high reliability, and small performance fluctuations after long use.

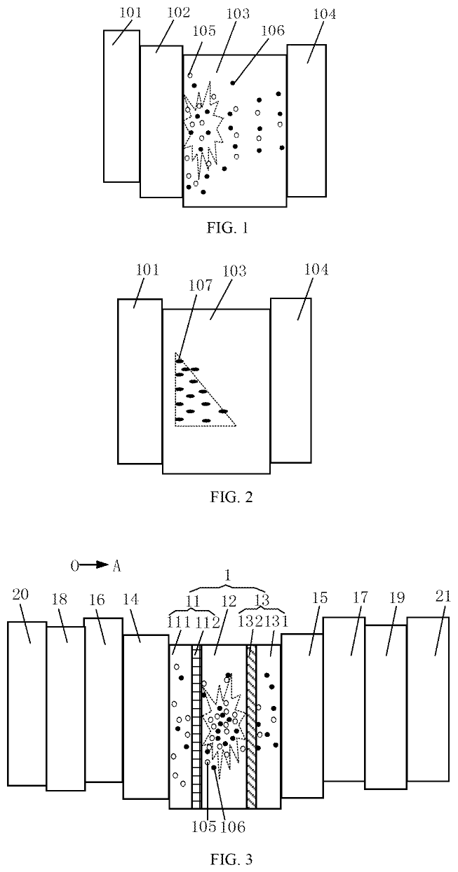

However, at present, due to the differences in cracking of different materials and device structures, various problems will arise in the actual use process. In the actual production stage, in order to solve various types of problems, the thicknesses of some film layers in OLED display apparatus will be changed according to the actual needs, which leads to problems as shown in FIG. 1 and FIG. 2, where FIG. 1 and FIG. 2 are the schematic structural diagrams of OLED display apparatuses in related art. Referring to FIG. 1, the OLED display apparatus includes a hole transporting layer (HTL layer) 101, a prime layer 102, an emitting layer (EML layer) 103 and a hole barrier layer (HBL layer) 104. When powered on, holes 105 and electrons 106 in the EML layer 103 are mainly compounded to form excitons at an interface of the prime layer 102 and the EML layer 103. Similarly, referring to FIG. 2, the OLED display apparatus includes the HTL layer 101, the EML layer 103 and the HBL layer 104. When powered on, the holes and the electrons in the EML layer 103 are mainly compounded to form the excitons 107 at the position of the EML layer 103 close to the HTL layer 101. Both FIG. 1 and FIG. 2 make the main luminous area close to the edge of the EML layer 103 (the dotted lines in FIG. 1 and FIG. 2 are the main luminous area), resulting in many screen defects, such as short T95 duration, LT overshoot phenomenon, and color deviation when using the screen for a long time. Among them, the above T95 duration refers to the duration used to reduce the luminous brightness of the OLED display apparatus to 95% of the initial brightness; LT overshoot phenomenon refers to the phenomenon that the brightness of the OLED display apparatus increases first and then decreases with time.

In addition, at present, users usually use OLED display screens with low brightness, but if the product life is tested at low brightness, the test time is very long and the feasibility is low. Generally, in order to ensure the accuracy and efficiency of the life test, an aging test of the OLED display screen is usually carried out using images with medium or high brightness, and then the life of the OLED display screen corresponding to low brightness is calculated by the ratio (i.e., an acceleration factor) of aging rate under medium, high brightness and low brightness. Under the condition that the life of the OLED display screen at the medium brightness is the same as that at the high brightness, a high acceleration factor also means that the life of the OLED display screen is longer at low brightness. However, the acceleration factor is very low due to the cracking difference of different OLED materials and the difference of the device structures.

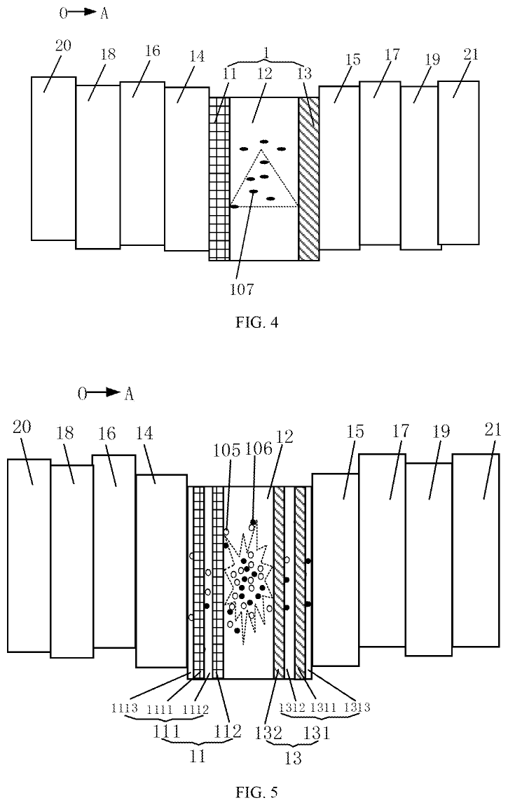

Based on the above, the embodiment of the present application provides a light-emitting device, referring to FIG. 3, FIG. 4 and FIG. 5, which includes: a luminescent layer 1 including a first sublayer 11, a second sublayer 12 and a third sublayer 13, and the second sublayer 12 is set between the first sublayer 11 and the third sublayer 13; the second sublayer 12 includes host materials and guest materials; and under the action of external energy, the excitons 107 are compounded in the second sublayer 12.

Among them, referring to FIG. 3, FIG. 4 and FIG. 5, the first sublayer 11 and the third sublayer 13 both include the host materials; a concentration of the excitons 107 in the second sublayer 12 is greater than a concentration of the excitons 107 in the first sublayer 11, and the concentration of the excitons 107 in the second sublayer 12 is greater than a concentration of the excitons 107 in the third sublayer 13.

The above luminescent layer may be any of a red luminescent layer, a green luminescent layer or a blue luminescent layer. At this time, the luminescent layer may be used for single color luminescence. The light-emitting device may simultaneously include three kinds of luminescent layers: the red luminescent layer, the green luminescent layer or the blue luminescent layer. Certainly, it may also include only one kind of the luminescent layer, for example, only include a plurality of red luminescent layers, or only include a plurality of green luminescent layers, or only include a plurality of blue luminescent layers. The details may be determined according to the actual requirements.

There is no specific restriction on the structure of the first sublayer described above. For example, the first sublayer described above may include a single-layer structure. Alternatively, the first sublayer described above may include a multi-layer structure. FIG. 3 shows the first sublayer 11 including a two-layer structure as an example; FIG. 4 shows the first sublayer 11 including one layer structure as an example: FIG. 5 shows the first sublayer 11 including a four-layer structure as an example. In the case that the first sublayer described above includes multi-layer structure, there is no limit on the structure of each layer, which is subject to the actual application.

There is no specific restriction on the structure of the second sublayer described above. For example, the second sublayer described above may include the single-layer structure shown in FIGS. 3-5, which is subject to the actual application.

There is no specific restriction on the structure of the third sublayer described above. For example, the third sublayer described above may include the single-layer structure. Alternatively, the third sublayer described above may include the multi-layer structure. FIG. 3 shows the third sublayer 13 including a two-layer structure as an example: FIG. 4 shows the third sublayer 13 including one layer structure as an example; FIG. 5 shows the third sublayer 13 including a four-layer structure as an example. In the case that the third sublayer described above includes the multi-layer structure, there is no limit on the structure of each layer, which is subject to the actual application.

The second sublayer described above includes the host materials and the guest materials. Generally, the guest materials is doped in the host materials. Here, take the blue luminescent layer as an example to illustrate, other color luminescent layer may refer to the blue luminescent layer, which will not be detailed here. The blue luminescent layer includes the host materials and the guest materials emitting blue light.

There is no specific restriction on the host materials described above. For example, the host materials described above may include hole-type host materials, when there are holes injected, the hole-type host materials are organic semiconductor materials that may realize the directional and orderly controlled migration of carriers under the action of electric field, so as to transfer charge. Alternatively, for example, the host materials described above may include electronic-type host materials, when there are electrons injected, the electronic-type host materials are organic semiconductor materials that may realize the directional and orderly controlled migration of carriers under the action of electric field, so as to transfer charge.

There is no specific limitation on a range of a doping ratio of the guest materials in the host materials. For example, the range of the doping ratio of the guest materials in the host materials may include 1-10%, specifically, the doping ratio may be 2%, 4%, 6%, 8% or 10%, and so on.

There is no specific restriction on the type of the external energy described above. For example, the external energy described above may include light, electricity, and so on.

There is no specific restriction on the concentration of the excitons described above in the first sublayer. For example, there can be no excitons in the first sublayer described above; alternatively, the first sublayer described above may include the excitons, and the concentration of the excitons in the first sublayer is less than the concentration of the excitons in the second sublayer.

There is no specific restriction on the concentration of the excitons described above in the third sublayer. For example, there can be no excitons in the third sublayer; alternatively, the third sublayer described above may include the excitons, and the concentration of the excitons in the third sublayer is less than the concentration of the excitons in the second sublayer.

There is no specific restriction on preparation processes of the first sublayer, the second sublayer and the third sublayer described above. For example, the above preparation processes may include an evaporation process, a coating process, etc. Among them, the evaporation process is highly feasible and has no obvious adverse effect on other characteristics of the light-emitting device.

There is no specific restriction on the types of the light-emitting device described above. For example, the light-emitting device described above may include a single OLED light-emitting device, that is, a single OLED; alternatively, the light-emitting device described above may include a Tandem OLED light-emitting device, that is, a tandem OLED.

At present, mass-produced OLED light-emitting devices usually include the host materials (RH) and the guest materials (RD), the host materials may transfer energy to the guest materials under the action of external energy such as light and electricity, so as to make the guest materials to emit light by the radiation transition. Specifically, under the electroexcitation of the OLED light-emitting device, the holes and the electrons will form excitons on the host materials, and the energy level of the excitons will be transferred from the host materials to the guest materials, and then through the radiation transition and luminescence of the guest materials, the luminescence of the light-emitting device is realized.

The light-emitting device provided by the embodiment of the present application includes the luminescent layer, the luminescent layer includes the first sublayer, the second sublayer and the third sublayer, the second sublayer is disposed between the first sublayer and the third sublayer; the second sublayer includes the host materials and the guest materials; under the action of external energy, the excitons are compounded in the second sublayer; where the first sublayer and the third sublayer both include the host materials; the concentration of the excitons in the second sublayer is greater than the concentration of the excitons in the first sublayer, and the concentration of the excitons in the second sublayer is greater than the concentration of the excitons in the third sublayer. Since the first sublayer and the third sublayer both do not include the guest materials, and the concentration of the excitons in the second sublayer is the greatest, then under the action of external energy, most of the holes 105 and electrons 106 shown in FIG. 3 and FIG. 5 are forced to recombine in the second sublayer 12 to form the excitons 107 shown in FIG. 4, that is, the content of the excitons in the second sublayer is the highest. The energy level of the excitons in the second sublayer is transferred from the host materials to the guest materials, and then through the radiation transition and luminescence of the guest materials, the main luminous area in the light-emitting device provided by the embodiment of the present application is located in the second sublayer, that is, the main luminous area is located in the middle of the luminescent layer, which makes the relative proportion of the electrons and the holes more balanced, then it may effectively improve the life of the light-emitting device, such as increasing the LT95 duration, reducing or even avoiding the LT overshoot phenomenon, and so on.

In addition, because the life of the light-emitting device provided by the embodiment of the present application has been significantly improved, the problem of low OLED life acceleration factor has been greatly improved, and the acceleration factor has been effectively increased, thus ensuring the life level of the light-emitting device at low brightness.

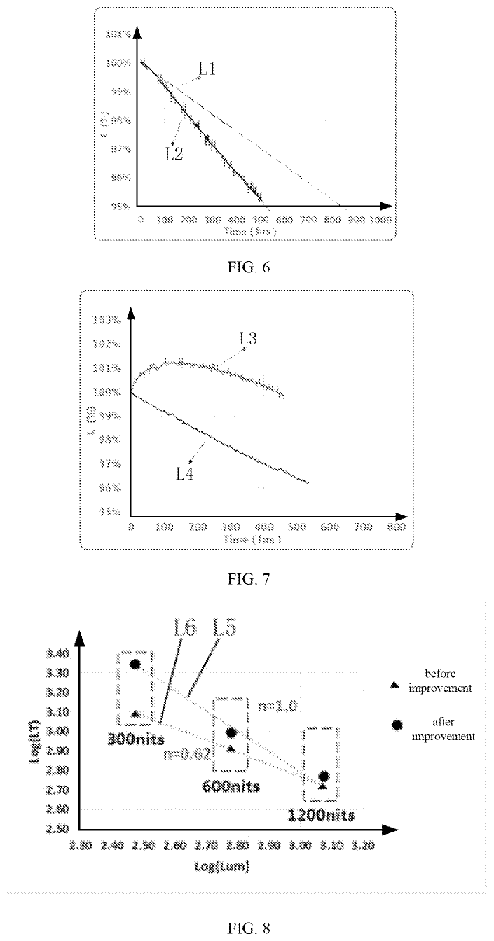

The above LT95 duration can be seen from FIG. 6. FIG. 6 is a LT95 duration comparison diagram between a comparison instance (the light-emitting device structure shown in FIG. 1) and the light-emitting device in the embodiment of the present application. The L1 curve is a LT95 duration curve of the light-emitting device provided by the embodiment of the present application, and the L2 curve is a LT95 duration curve of the comparison instance. In FIG. 6, the abscissa represents the duration in hrs, and the ordinate represents the brightness percentage. Referring to FIG. 6, under the same brightness, the LT95 duration of the light-emitting device provided by the embodiment of the present application is much longer than the LT95 duration of the comparison instance.

The above LT overshoot phenomenon can be seen from FIG. 7. FIG. 7 is a comparison diagram of LT overshoot phenomenon between the comparison instance (the light-emitting device structure shown in FIG. 1) and the light-emitting device in the embodiment of the present application. Where the L4 curve is a curve of the light-emitting device provided by the embodiment of the present application, and the L3 curve is a curve of the comparison instance. In FIG. 7, the abscissa represents the duration in hrs, and the ordinate represents the brightness percentage. Referring to FIG. 7, the L3 curve has obvious overshoot phenomenon in the time period from 0 to 500-600 hrs, while for the L4 curve, the brightness is reduced in the time period from 0 to 500-600 hrs all the time, and without the overshoot phenomenon.

The above acceleration factors can be seen from FIG. 8. FIG. 8 is a comparison diagram of the acceleration factors between the comparison instance (the light-emitting device structure shown in FIG. 2) and the light-emitting device in the embodiment of the present application. The L5 curve is the curve of the light-emitting device (after improvement) provided by the embodiment of the present application, and the L6 curve is the curve of the comparison instance (before improvement). In FIG. 8, the abscissa represents the logarithm of brightness, and the ordinate represents the logarithm of life. Referring to FIG. 8, after fitting the L5 curve, the acceleration factor afar improvement n=1.0 is obtained, and after fitting the L6 curve, the acceleration factor before improvement n=0.62 is obtained. Obviously, the acceleration factor after improvement of the light-emitting device is significantly increased.

Optionally, referring to FIG. 4, the first sublayer 11 and the third sublayer 13 are single-layer structures, and both include the host materials. Thus, the traditional luminescent layer is divided into three parts, namely the first sublayer, the second sublayer and the third sublayer of the present application. By designing a host-materials layer doped with non-guest light-emitting molecules close to the interface between the luminescent layer and an adjacent layer, most of the excitons may be forced to be located in the second sublayer under the action of external energy, so that the main luminous area of the light-emitting device provided by the embodiment of the present application is located in the middle of the luminescent layer, making the relative proportion of the electrons and the holes more balanced, avoiding breaking the balance of the electrons and the holes due to the excitons close to the interface between the huninescent layer and the adjacent layer, which may effectively improve the life of the light-emitting device, such as increasing the LT95 duration, reducing or even avoiding the LT overshoot phenomenon, etc., and ensure a higher acceleration factor, so that the life of the light-emitting device at low brightness remains at a higher level.

There is no specific restriction on preparation processes of the first sublayer, the second sublayer and the third sublayer described above. For example, the above preparation processes may include an evaporation process, a coating process, and so on. Among them, the evaporation process is highly feasible and has no obvious adverse effect on other characteristics of the light-emitting device.

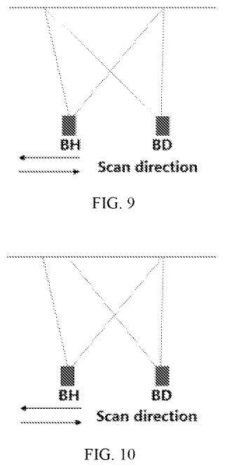

The following takes the evaporation process as an example to illustrate a specific manufacturing process of the light-emitting device in the embodiment of the present application. FIG. 9 shows the evaporation process in related art. At present, the evaporation sources of the host materials (BH) and the guest materials (BD) are used for evaporation at the same time. The angle plate of the evaporation is adjusted so that the two materials are evaporated in the same area at a certain evaporation rate and proportion. Referring to FIG. 9, it includes the host materials (BH) evaporation source and the guest materials (BD) evaporation source. Along the Scan Direction (a scanning direction), for example, scan to the left and then scan to the right. In the stage of scanning to the left, the BH evaporation source and BD evaporation source are evaporated at the same time in related art, so that the formed layer has both the BH material and the BD material.

FIG. 10 shows the evaporation in the embodiment of the present application. By adjusting the evaporation angle plate of the BH material and the BD material, when moving along the scanning direction, at the beginning and end of the scanning round trip, there is only one of the BH material or the BD material in partial film layers. Refer to FIG. 10 for details. For example, in the stage of scanning to the left, the BH material may be evaporated first to form the first sublayer, and after a period of time, for example, 2s, the BD material may be evaporated to form the second sublayer at the same time; in the stage of scanning to the right, the BH material and the BD material are still evaporated to form the second sublayer; in the period before the end, such as 2s, only the BH material is evaporated to form the third sublayer, and so on.

Optionally, referring to FIG. 4, the light-emitting device further includes a hole injection layer 18 disposed on a side of the first sublayer 11 away from the second sublayer 12; and a range of an absolute value of a difference between an energy value of a highest occupied molecular orbital HOMO of the first sublayer 11 and an energy value of a highest occupied molecular orbital HOMO of the second sublayer 12 includes 0.1-0.5 eV. So that through the cooperation between the HOMO energy value of the first sublayer and the HOMO energy value of the second sublayer, more excitons may be forced to be located in the second sublayer under the action of external energy, in other words, the main luminous area of the light-emitting device provided by the embodiment of the present application is located in the middle of the luminescent layer, avoiding breaking the balance of the electrons and the holes due to the excitons close to the interface, making the relative proportion of the electrons and the holes more balanced, which may effectively improve the life of the light-emitting device, and further increase the acceleration factor.

The highest occupied molecular orbital (HOMO) described above refers to the molecular orbital with the highest energy among the molecular orbitals occupied by the electrons. The energy value of the highest occupied molecular orbital is also known as the HOMO value.

There is no specific restriction on the absolute value of the difference between the energy value of the highest occupied molecular orbital HOMO of the first sublayer and the energy value of the highest occupied molecular orbital HOMO of the second sublayer. For example, the absolute value of the difference between the energy value of the highest occupied molecular orbital HOMO of the first sublayer and the energy value of the highest occupied molecular orbital HOMO of the second sublayer may be 0.1 eV, 0.2 eV, 0.3 eV, 0.4 eV or 0.5 eV, and so on.

Optionally, referring to FIG. 4, the light-emitting device further includes an electron injection layer 19 disposed on a side of the third sublayer 13 away from the second sublayer 12; a range of an absolute value of a difference between an energy value of a lowest unoccupied molecular orbital LUMO of the third sublayer 13 and an energy value of a lowest unoccupied molecular orbital LUMO of the second sublayer 12 includes 0.1-0.5 eV. So that through the cooperation between the LUMO energy value of the third sublayer and the LUMO energy value of the second sublayer, more excitons may be forced to be located in the second sublayer under the action of external energy, in other words, the main luminous area of the light-emitting device provided by the embodiment of the present application is located in the middle of the luminescent layer, avoiding breaking the balance of the electrons and the holes due to the excitons close to the interface, making the relative proportion of the electrons and the holes more balanced, which may effectively improve the life of the light-emitting device, and further increase the acceleration factor.

The lowest unoccupied molecular orbital (LUMO) described above refers to the molecular orbital with the lowest energy among the molecular orbitals unoccupied by the electrons. The energy value of the lowest unoccupied molecular orbital is also known as the LUMO value.

There is no specific restriction on the absolute value of the difference between the energy value of the lowest unoccupied molecular orbital LUMO of the third sublayer and the energy value of the lowest unoccupied molecular orbital LUMO of the second sublayer. For example, the absolute value of the difference between the energy value of the lowest unoccupied molecular orbital LUMO of the third sublayer and the energy value of the lowest unoccupied molecular orbital LUMO of the second sublayer may be 0.1 eV. 0.2 eV, 0.3 eV, 0.4 eV or 0.5 eV, and so on.

Optionally, referring to FIG. 4, along a direction perpendicular to the luminescent layer (the OA direction shown in the figure), a thickness of the second sublayer 12 is greater than a thickness of the first sublayer 11, and the thickness of the second sublayer 12 is greater than a thickness of the third sublayer 13. Thus, the thicknesses of the first sublayer and the third sublayer are very thin compared with the thickness of the second sublayer, and the host materials of the first sublayer and the third sublayer are less than that of the second sublayer. More excitons may be forced to be located in the second sublayer under the action of external energy, in other words, the main luminous area of the light-emitting device provided by the embodiment of the present application is located in the middle of the luminescent layer, avoiding breaking the balance of the electrons and the holes due to the excitons close to the interface, making the relative proportion of the electrons and the holes more balanced, which may effectively improve the life of the light-emitting device, and further increase the acceleration factor.

There is no specific restriction on the thicknesses of the first sublayer, the second sublayer, and the third sublayer. For example, a range of a ratio of the thickness of the first sublayer to the thickness of the second sublayer includes 20-30%. Specifically, the range of the ratio of the thickness of the first sublayer to the thickness of the second sublayer includes 20%, 25%, or 30%, etc. For example, a range of a ratio of the thickness of the third sublayer to the thickness of the second sublayer includes 20-30%. Specifically, the range of the ratio of the thickness of the third sublayer to the thickness of the second sublayer includes 20%, 25%, or 30%, etc. For example, when the thickness of the second sublayer is 100 Å, the thickness of the first sublayer and the thickness of the third sublayer may be 25 Å.

There is no specific restriction on magnitude of the thicknesses of the first sublayer and the third sublayer. For example, the thickness of the first sublayer may be the same as the thickness of the third sublayer; or, the thickness of the first sublayer may be different from the thickness of the third sublayer.

Optionally, in order to facilitate production and save process, referring to FIG. 4, along the direction perpendicular to the luminescent layer, the thickness of the first sublayer 11 is the same as the thickness of the third sublayer 13.

Optionally, referring to FIG. 3 and FIG. 5, the first sublayer 11 includes a first auxiliary sublayer 111 and a first electron barrier sublayer 112, the first electron barrier sublayer 112 is disposed between the first auxiliary sublayer 111 and the second sublayer 12.

Referring to FIG. 3 and FIG. 5, the third sublayer 13 includes a second auxiliary sublayer 131 and a first hole barrier sublayer 132, the first hole barrier sublayer 132 is disposed between the second auxiliary sublayer 131 and the second sublayer 12. So that the luminescent layer of the light-emitting device includes a five-layer structure, the first electron barrier sublayer in the five-layer structure can limit the penetration of the electrons from the second sublayer, and the first hole barrier sublayer can limit the penetration of the holes from the second sublayer, thus forcing most of the electrons and holes to recombine in the second sublayer, so that the main luminous area of the light-emitting device is located in the middle of the second sublayer, which effectively extends the life of the light-emitting device and improves the acceleration factor.

The first auxiliary sublayer described above refers to the layer used for light emission. There is no specific restriction on the material of the first auxiliary sublayer described above. For example, the material of the first auxiliary sublayer described above may include the host materials and the guest materials; alternatively, the material of the first auxiliary sublayer described above may only include the host materials.

There is no specific restriction on the thickness of the first auxiliary sublayer. For example, along the direction perpendicular to the luminescent layer, the thickness of the first auxiliary sublayer may be less than the thickness of the second sublayer; or, along the direction perpendicular to the luminescent layer, the thickness of the first auxiliary sublayer may be the same as the thickness of the second sublayer.

The first electron barrier sublayer described above has a strong blocking ability for the electrons and has little effect on hole migration, it can block the electrons in the second sublayer from penetrating the second sublayer and ensure that more electrons recombine with the holes in the second sublayer, thus increasing the number of the excitons and further improving the luminous efficiency. There is no specific restriction on the material of the above first electron barrier sublayer, for example, the material of the first electron barrier sublayer described above may only include the electron blocking material; or, the material of the first electron barrier sublayer described above may include the electron blocking material and the host materials; or, the material of the first electron barrier sublayer described above may include the electron blocking material, the host materials and the guest materials.

There is no specific restriction on the thickness of the above first electron barrier sublayer, for example, along the direction perpendicular to the luminescent layer, the thickness of the first electron barrier sublayer may be far less than the thickness of the second sublayer. At this time, it can not only block the electrons penetrate the second sublayer, thus limiting more electrons in the second sublayer and compounding with the holes, so that the main luminous area of the light-emitting device is located in the middle of the second sublayer, but also avoid the energy difference at the interface of the first electron barrier sublayer and the second sublayer caused by the too thick thickness of the first electron barrier sublayer, which leads to the recombination of the excitons on the interface of the first electron barrier sublayer and the second sublayer, and reduces the life of the light-emitting device.

The second auxiliary sublayer described above refers to the layer used for light emission. There is no specific restriction on the material of the second auxiliary sublayer described above. For example, the material of the second auxiliary sublayer described above may include the host materials and the guest materials; alternatively, the material of the second auxiliary sublayer described above may only include the host materials.

There is no specific restriction on the thickness of the second auxiliary sublayer. For example, along the direction perpendicular to the luminescent layer, the thickness of the second auxiliary sublayer may be less than the thickness of the second sublayer; or, along the direction perpendicular to the luminescent layer, the thickness of the second auxiliary sublayer may be the same as the thickness of the second sublayer.

The first hole barrier sublayer described above has a strong blocking ability for the holes and has little effect on electrons migration, it can block the holes in the second sublayer from penetrating the second sublayer and ensure that more boles recombine with the electrons in the second sublayer, thus increasing the number of the excitons and further improving the luminous efficiency. There is no specific restriction on the material of the above first hole barrier sublayer, for example, the material of the first hole barrier sublayer described above may only include the hole blocking material; or, the material of the first hole barrier sublayer described above may include the hole blocking material and the host materials; or, the material of the first hole barrier sublayer described above may include the hole blocking material, the host materials and the guest materials.

There is no specific restriction on the thickness of the above first hole barrier sublayer, for example, along the direction perpendicular to the luminescent layer, the thickness of the first hole barrier sublayer may be far less than the thickness of the second sublayer. At this time, it can not only block the holes penetrate the second sublayer, thus limiting more holes in the second sublayer and compounding with the electrons, so that the main luminous area of the light-emitting device is located in the middle of the second sublayer, but also avoid the energy difference at the interface of the first hole barrier sublayer and the second sublayer caused by the too thick thickness of the first hole barrier sublayer, which leads to the recombination of the excitons on the interface of the first hole barrier sublayer and the second sublayer, and reduces the life of the light-emitting device.

Optionally, the first auxiliary sublayer and the second auxiliary sublayer both include the host materials and the guest materials.

The first hole barrier sublayer includes a hole blocking material; the first electron barrier sublayer includes an electron blocking material. At this time, the first electron barrier sublayer can effectively limit the penetration of the electrons from the second sublayer, and the first hole barrier sublayer can effectively limit the penetration of the holes from the second sublayer, thus forcing most of the electrons and holes to recombine in the second sublayer, so that the main luminous area of the light-emitting device is located in the middle of the second sublayer, which effectively extends the life of the light-emitting device and improves the acceleration factor.

There is no specific restriction on preparation processes of the first auxiliary sublayer, the second auxiliary sublayer, the first electron barrier sublayer and the first hole barrier sublayer described above. For example, the above preparation processes may include an evaporation process, a coating process, etc. Among them, the evaporation process is highly feasible and has no obvious adverse effect on other characteristics of the light-emitting device.

The following takes the evaporation process as an example to illustrate a manufacturing process of the light-emitting device in the embodiment of the present application.

First, open the evaporation source of the host materials (BH) and the guest materials (BD) at the same time, and evaporate the BH material and the BD material at the same time to form the first auxiliary sublayer; after forming the first auxiliary sublayer with a preset thickness, close the evaporation source of the BH material and the BD material at the same time, and open the evaporation source of the electron blocking material to form the first electron barrier sublayer; after forming the first electron barrier sublayer with a preset thickness, close the evaporation source of the electron blocking material, open the evaporation source of the BH material and the BD material at the same time to form the second sublayer; after forming the second sublayer with a preset thickness, close the evaporation source of the BH material and the BD material at the same time, open the evaporation source of the hole blocking material to form the first hole barrier sublayer; after forming the first hole barrier sublayer with a preset thickness, close the evaporation source of the hole blocking material, open the evaporation source of the BH material and the BD material at the same time to form the second auxiliary sublayer.

Optionally, the first auxiliary sublayer and the second auxiliary sublayer both include the host materials and the guest materials.

The first hole barrier sublayer includes the host materials, the guest materials and the hole blocking material; the first electron barrier sublayer includes the host materials, the guest materials and the electron blocking material. At this time, the first electron barrier sublayer can effectively limit the penetration of the electrons from the second sublayer, and the first hole barrier sublayer can effectively limit the penetration of the holes from the second sublayer, thus forcing most of the electrons and holes to recombine in the second sublayer, so that the main luminous area of the light-emitting device is located in the middle of the second sublayer, which effectively extends the life of the light-emitting device and improves the acceleration factor.

There is no specific restriction on preparation processes of the first auxiliary sublayer, the second auxiliary sublayer, the first electron barrier sublayer and the first hole barrier sublayer described above. For example, the above preparation processes may include an evaporation process, a coating process, etc. Among them, the evaporation process is highly feasible and has no obvious adverse effect on other characteristics of the light-emitting device.

The following takes the evaporation process as an example to illustrate a manufacturing process of the light-emitting device in the embodiment of the present application.

First, open the evaporation source of the host materials (BH) and the guest materials (BD) at the same time, and evaporate the BH material and the BD material at the same time to form the first auxiliary sublayer: after forming the first auxiliary sublayer with a preset thickness, further open the evaporation source of the electron blocking material to form the first electron barrier sublayer; after forming the first electron barrier sublayer with a preset thickness, close the evaporation source of the electron blocking material, to form the second sublayer: after forming the second sublayer with a preset thickness, further open the evaporation source of the hole blocking material to form the first hole barrier sublayer; after forming the first hole barrier sublayer with a preset thickness, close the evaporation source of the hole blocking material, to form the second auxiliary sublayer.

Optionally, referring to FIG. 3 and FIG. 5, along the direction perpendicular to the luminescent layer, the thickness of the second sublayer 12 is greater than a thickness of the first hole barrier sublayer 132, and the thickness of the second sublayer 12 is greater than a thickness of the first electron barrier sublayer 112. Thus, the thicknesses of the first hole barrier sublayer and the first electron barrier sublayer are very thin compared with the thickness of the second sublayer, more excitons may be forced to be located in the second sublayer under the action of external energy, meanwhile, which avoids generating energy levels at the interface between the second sublayer and the first hole barrier sublayer or the first electron barrier sublayer due to the too thick thicknesses of the first hole barrier sublayer and the first electron barrier sublayer. So that the main luminous area of the light-emitting device provided by the embodiment of the present application is located in the middle of the luminescent layer, avoiding breaking the balance of the electrons and the holes due to the excitons close to the interface, making the relative proportion of the electrons and the holes more balanced, which may effectively improve the life of the light-emitting device, and further increase the acceleration factor.

There is no specific restriction on the thicknesses of the first hole barrier sublayer, the second sublayer, and the first electron barrier sublayer. For example, a range of a ratio of the thickness of the first hole barrier sublayer to the thickness of the second sublayer includes 1-5%. Specifically, the range of the ratio of the thickness of the first hole barrier sublayer to the thickness of the second sublayer includes 1%, 2%, 3%, 4% or 5% etc. For example, a range of a ratio of the thickness of the first electron barrier sublayer to the thickness of the second sublayer includes 1-5%. Specifically, the range of the ratio of the thickness of the first electron barrier sublayer to the thickness of the second sublayer includes 1%, 2%, 3%, 4% or 5% etc. For example, when the thickness of the second sublayer is 100 Å, the thickness of the first hole barrier sublayer and the thickness of the first electron barrier sublayer may be 2 Å.

There is no specific restriction on magnitude of the thicknesses of the first hole barrier sublayer and the first electron barrier sublayer. For example, the thickness of the first hole barrier sublayer may be the same as the thickness of the first electron barrier sublayer; or, the thickness of the first hole barrier sublayer may be different from the thickness of the first electron barrier sublayer.

Optionally, in order to facilitate production and save process, referring to FIG. 3 and FIG. 5, along the direction perpendicular to the luminescent layer, the thickness of the first hole barrier sublayer 132 is the same as the thickness of the first electron barrier sublayer 112.

Optionally, referring to FIG. 5, the first sublayer 11 further includes a second electron barrier sublayer 1111, the second electron barrier sublayer 1111 is disposed on a side of the first electron barrier sublayer 112 away from the second sublayer 12 to divide the first auxiliary sublayer 111 into two parts. So that the luminescent layer of the light-emitting device includes a seven-layer structure, the first electron barrier sublayer in the seven-layer structure can limit the penetration of the electrons from the second sublayer, however, there may still be a small number of the electrons penetrating from the second sublayer into the first auxiliary sublayer, and then the second electron barrier sublayer can limit the penetration of the electrons from the first auxiliary sublayer, so that the main luminous area of the light-emitting device is located in the middle of the luminescent layer, which effectively extends the life of the light-emitting device and improves the acceleration factor.

The second electron barrier sublayer described above has a strong blocking ability for the electrons and has little effect on hole migration, it can block the electrons in the first auxiliary sublayer from penetrating the first auxiliary sublayer and ensure that more electrons recombine with the holes in the first auxiliary sublayer, thus increasing the number of the excitons and further improving the luminous efficiency. There is no specific restriction on the material of the above second electron barrier sublayer, for example, the material of the second electron barrier sublayer described above may only include the electron blocking material; or, the material of the second electron barrier sublayer described above may include the electron blocking material and the host materials; or, the material of the second electron barrier sublayer described above may include the electron blocking material, the host materials and the guest materials.

There is no specific restriction on the thickness of the above second electron barrier sublayer, for example, along the direction perpendicular to the luminescent layer, the thickness of the second electron barrier sublayer may be far less than the thickness of the second sublayer; or, the thickness of the second electron barrier sublayer may be the same as the thickness of the first electron barrier sublayer, which is subject to the actual application.

It should be noted that, referring to FIG. 5, the second electron barrier sublayer 1111 divides the first auxiliary sublayer 111 into two parts, one part is the first part 1112, and the other part is the second part 1113. There is no restriction on the specific materials of the first part 1112 and the second part 1113. For example, the materials of the first part 1112 and the second part 1113 may both include the host materials and the guest materials; or, the materials of the first part 1112 and the second part 1113 may both include the host materials, which is subject to the actual application.

Optionally, the second electron barrier sublayer includes the host materials, the guest materials and the electron blocking material; and a doping concentration of the electron blocking material in the host materials of the second electron barrier sublayer is greater than a doping concentration of the electron blocking material in the host materials of the first electron barrier sublayer. So that the first electron barrier sublayer can limit the penetration of the electrons from the second sublayer, however, there may still be a small number of the electrons penetrating from the second sublayer into the first auxiliary sublayer. Since the doping concentration of the electron blocking material in the host materials of the second electron barrier sublayer is greater, the second electron barrier sublayer can further limit the penetration of the electrons from the first auxiliary sublayer, so that the main luminous area of the light-emitting device is located in the middle of the luminescent layer, which effectively extends the life of the light-emitting device and improves the acceleration factor.

Optionally, referring to FIG. 5, the third sublayer 13 further includes a second bole barrier sublayer 1311, the second hole barrier sublayer 1311 is disposed on a side of the first hole barrier sublayer 132 away from the second sublayer 12 to divide the second auxiliary sublayer 131 into two parts. So that the luminescent layer of the light-emitting device includes a nine-layer structure, the first hole barrier sublayer in the nine-layer structure can limit the penetration of the holes from the second sublayer, however, there may still be a small number of the holes penetrating from the second sublayer into the second auxiliary sublayer, and then the second hole barrier sublayer can limit the penetration of the holes from the second auxiliary sublayer, so that the main luminous area of the light-emitting device is located in the middle of the luminescent layer, which effectively extends the life of the light-emitting device and improves the acceleration factor.

The second hole barrier sublayer described above has a strong blocking ability for the holes and has little effect on electrons migration, it can block the holes in the second auxiliary sublayer from penetrating the second auxiliary sublayer and ensure that more holes recombine with the electrons in the second auxiliary sublayer, thus increasing the number of the excitons and further improving the luminous efficiency. There is no specific restriction on the material of the above second hole barrier sublayer, for example, the material of the second hole barrier sublayer described above may only include the hole blocking material; or, the material of the second hole barrier sublayer described above may include the hole blocking material and the host materials; or, the material of the second hole barrier sublayer described above may include the hole blocking material, the host materials and the guest materials.

There is no specific restriction on the thickness of the above second hole barrier sublayer, for example, along the direction perpendicular to the luminescent layer, the thickness of the second hole barrier sublayer may be far less than the thickness of the second sublayer; or, the thickness of the second hole barrier sublayer may be the same as the thickness of the first hole barrier sublayer, which is subject to the actual application.

It should be noted that, referring to FIG. 5, the second hole barrier sublayer 1311 divides the second auxiliary sublayer 131 into two parts, one part is the third part 1312, and the other part is the fourth part 1313. There is no restriction on the specific materials of the third part 1312 and the fourth part 1313. For example, the materials of the third part 1312 and the fourth part 1313 may both include the host materials and the guest materials; or, the materials of the third part 1312 and the fourth part 1313 may both include the host materials, which is subject to the actual application.

Optionally, the second hole barrier sublayer includes the host materials, the guest materials and the hole blocking material; and a doping concentration of the hole blocking material in the host materials of the second hole barrier sublayer is greater than a doping concentration of the hole blocking material in the host materials of the first hole barrier sublayer. So that the first hole barrier sublayer can limit the penetration of the holes from the second sublayer, however, there may still be a small number of the holes penetrating from the second sublayer into the second auxiliary sublayer. Since the doping concentration of the hole blocking material in the host materials of the second holes barrier sublayer is greater, the second hole barrier sublayer can further limit the penetration of the holes from the second auxiliary sublayer, so that the main luminous area of the light-emitting device is located in the middle of the luminescent layer, which effectively extends the life of the light-emitting device and improves the acceleration factor.

Optionally, referring to FIG. 3 and FIG. 5, the light-emitting device further includes an electron barrier layer 14 and a hole barrier layer 15, the electron barrier layer 14 is disposed on a side of the first sublayer 11 away from the second sublayer 12, and the hole barrier layer 15 is disposed on a side of the third sublayer 13 away from the second sublayer 12.

A distance between the first electron barrier sublayer and an interface of the first auxiliary sublayer and the electron barrier layer is the same as a distance between the first hole barrier sublayer and an interface of the second auxiliary sublayer and the hole barrier layer.

The above electron barrier layer can block the electrons in the luminescent layer from penetrating the luminescent layer and ensure that more electrons recombine with the holes in the luminescent layer, thus increasing the number of the excitons and further improving the luminous efficiency.

The above hole barrier layer can block the holes in the luminescent layer from penetrating the luminescent layer and ensure that more holes recombine with the electrons in the luminescent layer, thus increasing the number of the excitons and further improving the luminous efficiency.

There is no specific restriction on the distance between the first electron barrier sublayer and an interface of the first auxiliary sublayer and the electron barrier layer, and the distance between the first hole barrier sublayer and an interface of the second auxiliary sublayer and the bole barrier layer. For example, a range of the above distance between the first electron barrier sublayer and an interface of the first auxiliary sublayer and the electron barrier layer may include 10-30%. Specifically, when the thickness of the luminescent layer is 100 Å, the distance between the first electron barrier sublayer and an interface of the first auxiliary sublayer and the electron barrier layer may be 10 Å, 20 Å or 30 Å, and so on. For example, a range of the above distance between the first hole barrier sublayer and an interface of the second auxiliary sublayer and the hole barrier layer may include 10-30%. Specifically, when the thickness of the luminescent layer is 100 Å, the distance between the first hole barrier sublayer and an interface of the second auxiliary sublayer and the hole barrier layer may be 10 Å, 20 Å or 30 Å, and so on.

Optionally, referring to FIG. 2, FIG. 3 and FIG. 5, the light-emitting device also includes an anode 20 and a cathode 21, the anode 20 is arranged on a side of the hole injection layer 18 away from the first sublayer 11, and the cathode 21 is arranged on a side of the electron injection layer 19 away from the third sublayer 13.

Referring to FIG. 2, FIG. 3 and FIG. 5, the light-emitting device also includes a hole transport layer 16 and an electron transport layer 17, the hole transport layer 16 is arranged between the hole injection layer 18 and the electron barrier layer 14, and the electron transport layer 17 is arranged between the electron injection layer 19 and the hole barrier layer 15.

There is no specific restriction on the material of the above anode. For example, the material of the above anode may include indium tin oxide (ITO).

There is no specific restriction on the manufacturing process of the above anode. For example, a glass plate with the ITO may be ultrasonically treated in deionized water, and then dried at 100° C. to obtain the anode.

Optionally, the light-emitting device also includes an encapsulation layer, which is arranged on the side of the cathode away from the luminescent layer and covers the luminescent layer. Thus, the light-emitting device can be well encapsulated through the encapsulation layer to prevent the light-emitting device from being eroded by water vapor and oxygen.

There is no specific restriction on the structure of the above encapsulation layer. For example, the encapsulation layer may be a single-layer structure, for example, the encapsulation layer may only include one inorganic layer; alternatively, the encapsulation layer may be a multi-layer structure, for example, the encapsulation layer may include a first inorganic encapsulation layer, an organic encapsulation layer and a second inorganic encapsulation layer, which is subject to the actual application.

In another aspect, the embodiment of the present disclosure further provides a display apparatus, including the above light-emitting device.

The above display apparatus may be a display apparatus with the touch function, or it may also be a display apparatus with the fold or curl function, or it may also be a display apparatus with both the touch function and the fold function, which is not limited here. The display apparatus may be a flexible display apparatus (also known as a flexible screen) or a rigid display apparatus (that is, a display screen that cannot be bent), which is not limited here.

The above display apparatus may be an OLED display apparatus, a Micro LED display apparatus or a Mini LED display apparatus.

The display apparatus may be any product or component with display function such as TV, digital camera, mobile phone, tablet computer, etc.; the above display apparatus may also be used in the fields of identity recognition, medical devices, etc. Products that have been promoted or have good prospects for promotion include security identity authentication, intelligent door locks, medical image acquisition, etc. The display apparatus has the advantages of long service life, low cost, good display effect, high stability, high contrast, good imaging quality and high product quality.

A large number of specific details are described in the specification provided here. However, it can be understood that the embodiments of the present application can be practiced without these specific details. In some examples, the well-known methods, structures and techniques are not shown in detail so as not to obscure the understanding of this specification.

Finally, it should be noted that: the above embodiments are only used to illustrate the technical solution of the present application, not to limit it; although the present application has been described in detail with reference to the preceding embodiments, those skilled in the art should understand that they can still modify the technical solutions recorded in the preceding embodiments or replace some of the technical features equally; however, these modifications or substitutions do not make the essence of the corresponding technical solutions deviate from the spirit and scope of the technical solutions of the embodiments of the present application.

1. A light-emitting device, comprising:
a luminescent layer comprising a first sublayer, a second sublayer and a third sublayer, wherein the second sublayer is disposed between the first sublayer and the third sublayer; the second sublayer comprises host materials and guest materials; under the action of external energy, excitons are compounded in the second sublayer;
wherein the first sublayer and the third sublayer both comprise the host materials; a concentration of the excitons in the second sublayer is greater than a concentration of the excitons in the first sublayer, and the concentration of the excitons in the second sublayer is greater than a concentration of the excitons in the third sublayer.

2. The light-emitting device according to claim 1, wherein the first sublayer and the third sublayer are single-layer structures, and both comprise the host materials.

3. The light-emitting device according to claim 2, wherein the light-emitting device further comprises a hole injection layer disposed on a side of the first sublayer away from the second sublayer; and
a range of an absolute value of a difference between an energy value of a highest occupied molecular orbital HOMO of the first sublayer and an energy value of a highest occupied molecular orbital HOMO of the second sublayer comprises 0.1-0.5 eV.

4. The light-emitting device according to claim 2, wherein the light-emitting device further comprises an electron injection layer disposed on a side of the third sublayer away from the second sublayer; and
a range of an absolute value of a difference between an energy value of a lowest unoccupied molecular orbital LUMO of the third sublayer and an energy value of a lowest unoccupied molecular orbital LUMO of the second sublayer comprises 0.1-0.5 eV.

5. The light-emitting device according to claim 2, wherein along a direction perpendicular to the luminescent layer, a thickness of the second sublayer is greater than a thickness of the first sublayer, and the thickness of the second sublayer is greater than a thickness of the third sublayer.

6. The light-emitting device according to claim 5, wherein along the direction perpendicular to the luminescent layer, the thickness of the first sublayer is the same as the thickness of the third sublayer.

7. The light-emitting device according to claim 1, wherein the first sublayer comprises a first auxiliary sublayer and a first electron barrier sublayer, the first electron barrier sublayer is disposed between the first auxiliary sublayer and the second sublayer; and
the third sublayer comprises a second auxiliary sublayer and a first hole barrier sublayer, the first hole barrier sublayer is disposed between the second auxiliary sublayer and the second sublayer.

8. The light-emitting device according to claim 7, wherein the first auxiliary sublayer and the second auxiliary sublayer both comprise the host materials and the guest materials; and
the first hole barrier sublayer comprises a hole blocking material, and the first electron barrier sublayer comprises an electron blocking material.

9. The light-emitting device according to claim 7, wherein the first auxiliary sublayer and the second auxiliary sublayer both comprise the host materials and the guest materials; and
the first hole barrier sublayer comprises the host materials, the guest materials and a hole blocking material; the first electron barrier sublayer comprises the host materials, the guest materials and an electron blocking material.

10. The light-emitting device according to claim 7, wherein along a direction perpendicular to the luminescent layer, a thickness of the second sublayer is greater than a thickness of the first hole barrier sublayer, and the thickness of the second sublayer is greater than a thickness of the first electron barrier sublayer.

11. The light-emitting device according to claim 10, wherein along the direction perpendicular to the luminescent layer, the thickness of the first hole barrier sublayer is the same as the thickness of the first electron barrier sublayer.

12. The light-emitting device according to claim 9, wherein the first sublayer further comprises a second electron barrier sublayer, the second electron barrier sublayer is disposed on a side of the first electron barrier sublayer away from the second sublayer to divide the first auxiliary sublayer into two parts.

13. The light-emitting device according to claim 12, wherein the second electron barrier sublayer comprises the host materials, the guest materials and the electron blocking material; and
a doping concentration of the electron blocking material in the host materials of the second electron barrier sublayer is greater than a doping concentration of the electron blocking material in the host materials of the first electron barrier sublayer.

14. The light-emitting device according to claim 9, wherein the third sublayer further comprises a second hole barrier sublayer, the second hole barrier sublayer is disposed on a side of the first hole barrier sublayer away from the second sublayer to divide the second auxiliary sublayer into two parts.

15. The light-emitting device according to claim 14, wherein the second hole barrier sublayer comprises the host materials, the guest materials and the hole blocking material; and
a doping concentration of the hole blocking material in the host materials of the second hole barrier sublayer is greater than a doping concentration of the hole blocking material in the host materials of the first hole barrier sublayer.

16. The light-emitting device according to claim 7, wherein the light-emitting device further comprises an electron barrier layer and a hole barrier layer, the electron barrier layer is disposed on a side of the first sublayer away from the second sublayer, and the hole barrier layer is disposed on a side of the third sublayer away from the second sublayer;
a distance between the first electron barrier sublayer and an interface of the first auxiliary sublayer and the electron barrier layer is the same as a distance between the first hole barrier sublayer and an interface of the second auxiliary sublayer and the hole barrier layer.

17. A display apparatus, comprising the light-emitting device according to claim 1.

18. The display apparatus according to claim 17, wherein the first sublayer and the third sublayer are single-layer structures, and both comprise the host materials.

19. The display apparatus according to claim 18, wherein the light-emitting device further comprises a hole injection layer disposed on a side of the first sublayer away from the second sublayer; and
a range of an absolute value of a difference between an energy value of a highest occupied molecular orbital HOMO of the first sublayer and an energy value of a highest occupied molecular orbital HOMO of the second sublayer comprises 0.1-0.5 eV.

20. The display apparatus according to claim 18, wherein the light-emitting device further comprises an electron injection layer disposed on a side of the third sublayer away from the second sublayer; and
a range of an absolute value of a difference between an energy value of a lowest unoccupied molecular orbital LUMO of the third sublayer and an energy value of a lowest unoccupied molecular orbital LUMO of the second sublayer comprises 0.1-0.5 eV.
